(19) United States
(12) Patent Application Publication
(10) Pub. No.: US 2013/0048068 A1
(43) Pub. Date: Feb. 28, 2013

(54) METHOD OF MANUFACTURING MESOSCOPIC SOLAR CELLS

(71) Applicants: Yi-Bing Cheng, Victoria (AU); Hasitha Weerasinghe, Victoria (AU); Prasad M. Sirimanne, Colombo (LK); Fuzhi Huang, Rowville (AU)

(72) Inventors: Yi-Bing Cheng, Victoria (AU); Hasitha Weerasinghe, Victoria (AU); Prasad M. Sirimanne, Colombo (LK); Fuzhi Huang, Rowville (AU)

(21) Appl. No.: 13/394,978

(22) PCT Filed: Sep. 10, 2010
(86) PCT No.: PCT/AU2010/001169

§ 371 Date: May 23, 2012

(30) Foreign Application Priority Data
Sep. 10, 2009 (AU) 2009904376

(51) Int. Cl. H01L 31/18; H01L 31/0224

(52) U.S. Cl. 136/256; 438/98; 257/E31.124

(57) ABSTRACT

A method of manufacturing a dye sensitised solar cell or other mesoscopic solar cell, including the steps of coating at least a portion of a surface of a substrate with an electrode film or other functional layer, and applying an isostatic pressure over the coated substrate to thereby compact the electrode film or functional layer on the substrate.

### INTRODUCTION TO THE INVENTION

The present invention is generally directed to a method of manufacturing mesoscopic solar cells such as dye sensitised solar cells (DSSC) and quantum dots sensitised solar cells. The present invention will be specifically described in relation to the manufacture of flexible DSSCs having polymer substrates. It is however to be appreciated that the present invention is not limited to this application, and is also applicable for use in the manufacture of mesoscopic solar cells having substrates of other materials including metal, ceramic and glass, as well as polymer.

### BACKGROUND TO THE INVENTION

Dye sensitised solar cells (DSSCs) or other mesoscopic solar cells (for example quantum dots sensitised solar cells) provide a low cost alternative to more conventional silicon based photovoltaic devices. DSSC devices are comprised of multiple layers of thin films, from a few nanometres to tens of micrometres in thickness, used for different functions. For conventional DSSC devices, the thin films, such as working electrodes, which are usually made of nano TiO₂ particles, are coated on the surface of conductive glass substrates and subsequently heated to about 500° C. to form mechanically strong and electrically conductive mesoporous films. When polymer substrates are used to produce flexible DSSCs, low temperature processing techniques have to be used because of the instability at about 250° C. for most polymer materials. The benefit of flexible DSSCs is that they are relatively light in weight and can be supported on a variety of different surfaces including surfaces having intricate curves. Mechanical compression techniques, such as rolling and uniaxial pressing, have been developed to compact mesoporous electrode films on polymer substrates. In the case of rolling pressing, the polymer substrate coated with the material for forming the electrode film is rolled under pressure between opposing rollers, while the coated substrate is compressed between opposing rigid dies in uniaxial pressing. However these methods have difficulties in achieving good film uniformity on the substrate when the films are thin and particularly when the film size is large. This is because as the films can be as little as only a few hundreds of nanometres thick, the rollers and die surfaces must be manufactured to very high tolerances which are difficult to achieve. Any misalignment or minor surface imperfection on the roller or die surfaces will make them unusable or result in inconsistent and imperfect compaction of the film. Furthermore, these methods are incapable of manufacturing solar panels on polymer substrates that are curved or have intricate shapes.

The working electrode film needs to be sensitised with a photosensitive medium. In the case of DSSCs, this medium is a photosensitive dye (sensitised quantum dots are utilized in quantum dots sensitised solar cells).

The electrode film of a DSSC is normally sensitised by soaking the electrode film in a photosensitive dye solution over an extended period to allow the dye molecules to be distributed through the electrode film. This soaking process can typically takes about 10 to 12 hours. It would be advantageous to be able to eliminate this soaking process to reduce the time to produce a DSSC and to facilitate continuous production process for such DSSCs.

Another more general problem associated with DSSC devices is that photosensitive dyes can only have a limited light absorption range. This limits the degree of electrons that can be released from the dye sensitised electrode film thereby also limiting the overall photoelectric conversion efficiency of the DSSC. It would be desirable for multiple sensitisers with different light absorption wavelengths to be incorporated into a DSSC device, but this is not possible using current manufacturing processes.

### SUMMARY OF THE INVENTION

It would therefore be advantageous to be able to have a method for manufacturing mesoscopic solar cells that avoid one or more of the problems associated with known manufacturing methods.

With this in mind, according to one aspect of the present invention, there is provided a method of manufacturing a dye sensitised solar cell or other mesoscopic solar cell, including the steps of:
a) coating at least a portion of a surface of a substrate with an electrode film or other functional layer, and
b) applying an isostatic pressure over the coated substrate to thereby compact the electrode film or functional layer on the substrate.

Different forms of mesoscopic solar cells may be manufactured according to the present invention, including dye sensitised solar cells wherein the functional layer is a dye sensitised electrode film, or a quantum dots sensitised solar cells wherein the functional layer is a quantum dot sensitised electrode film.

The functional layer may also include a counter electrode or other conducting layer of the mesoscopic solar cell.

The electrode film or functional layer may be in the form of a layer of particles, rods, tubes, or plates made from materials such as TiO₂, carbon or carbon nanotubes. Alternatively, the electrode film or functional layer may be made of surface modified TiO₂ particles, rods, tubes or plates which have been pre-sensitised/dyed. The advantage of having a pre-dyed electrode film for a DSSC layer is that the soaking process normally used to dye sensitise the electrode film is not required.

According to another preferred feature of the present invention, two or more electrode layers may be supported on the substrate, with each electrode layer sensitised with a different dye. The advantage of this configuration is that the light absorption range of the DSSC can be wider than conventional DSSCs sensitised by only a single dye.

Therefore, the manufacturing method according to a preferred aspect of the present invention includes forming a first said electrode film on a first said substrate, forming a second said electrode film on a second said substrate, bringing the first and second electrode films in face to face contact, subjecting the first and second electrode films to isostatic pressure to thereby compact the second electrode film to the first electrode film, and separating the second substrate from the second electrode film.

Alternatively, the manufacturing method according to the present invention may further include forming a first said electrode film on a said substrate, applying a second said electrode film in the form of a powder over the first electrode film, and applying isostatic pressure on the first and second electrode films to compact said electrode film on the first electrode film.

Preferably, the first electrode film is sensitised with a first sensitiser, whereas the second electrode film is sensitised with a second sensitiser.

The substrate may be formed of a flexible polymer material. It is also envisaged that the substrate may be formed from metal, ceramic or glass.

The flexible bag may be a vacuum bag, and the coated substrate may be vacuum sealed within the vacuum bag by evacuating the air therefrom.

The isostatic pressure, being a uniform pressure in all directions, may be applied to the coated substrate within a pressure chamber in either a free mould (wet bag) or a coarse mould (damp bag) or a fixed mould (dry bag) pressing. Three styles of isostatic compression tooling can be used. In the free mould (wet bag) tooling, the coated substrate is placed into a sealed flexible mould or flexible bag, which is then immersed into a pressure chamber. In free mould tooling the mould or bag is removed and filled outside the pressure chamber. In coarse mould (damp bag) tooling, the mould or bag is instead located within the pressure chamber, but filled from outside the chamber. In fixed mould (dry bag) tooling, the mould or bag is contained and filled within the pressure chamber, which facilitates automation of the process.

Liquid such as water or oil may be used as a pressure medium within the pressure chamber in wet bag pressing. Alternatively, an elastomer mould fixed to the pressure vessel may be used as a pressure medium in dry-bag pressing. The pressure medium may also be in a gas form such as air. Preferably a pressure in the range of 5 MPa to 2000 MPa may be applied.

It is not necessary for any heat to be applied to the coated substrate using the method according to the present invention. Therefore, the coated substrate may be subjected to a cold isostatic pressure (CIP) within the pressure chamber. It is however also envisaged that the coated substrate may be subjected to a degree of heating. For example, the pressure medium within the pressure chamber may be heated to thereby apply heat to the coated substrate during the isostatic pressurization. The maximum heating temperature will be limited by the thermal stability temperature of the substrate material.

The method according to the present invention may be used to fabricate both porous and dense electrode films and functional layers. The electrode film or functional layer may be printed or otherwise deposited on to the surface of the substrate in a variety of different patterns. For example, the electrode film may be deposited as a series of discrete strips over the substrate surface. Alternatively, the electrode film may be deposited over the entire substrate surface. The film may be applied to the substrate using known printing processes, including offset and inkjet printing, dip coating, spray coating, reel to reel printing, screen printing or doctor blading, etc. As is the case for most DSSCs, the electrode film may be formed from a layer of nano TiO₂ particles which forms an electrically conductive mesoporous film which can then be dye sensitised. The electrode film may also be formed from nano TiO₂ particles that are pre-coated with sensitisers or dye molecules. A dense blocking layer can also be produced by cold or warm isostatic pressing. The method according to the present invention can also be used to consolidate electrode films for DSSCs or other mesoscopic solar cells on metal or glass substrates.

The application of an isostatic pressure within the pressure chamber ensures that an electrode film with desirable porosity, high strength and uniformity can be achieved. The isostatic pressure also ensures that the electrode film properly adheres to the surface of the substrate.

According to another aspect of the present invention, there is provided a dye sensitised solar cell manufactured according to the method as described above. The method according to the present invention allows the manufacture of solar panels using DSSCs having large surface areas, with curved or intricate shapes to be produced.

The invention provides a number of advantages over presently used rolling and uniaxial pressing techniques in producing flexible DSSCs or mesoscopic solar cells. Thin films with high uniformity can be produced according to the method of the present invention thereby improving the solar cell efficiency and durability. The method according to the present invention is also more suitable for processing large size thin films of nanometre to millimetre thicknesses. The method according to the present invention also facilitates the production of non flat solar panels on polymer, metal or glass substrates.

### BRIEF DESCRIPTION OF THE DRAWINGS

It will be convenient to further describe the invention with reference to the accompanying drawings which illustrate preferred embodiments of the present invention. Other embodiments are possible, and consequently the particularity of the accompanying drawings is not to be understood as superseding the generality of the preceding description of the invention.

In the drawings:

FIG. 1 is a schematic diagram showing cold isostatic pressing within a pressure chamber according to the present invention;

FIG. 2 is a Table showing the photoelectric conversion efficiency obtained for different TiO₂ electrodes;

FIG. 3 is a graph showing the Incident Photon to Current Efficiency (IPCE) of two different photosensitive dyes and their combined IPCE Spectra according to the present invention; and

FIG. 4 is a schematic view showing the various steps required to produce a DSSC according to the present invention.

### DETAILED DESCRIPTION OF THE PRESENT INVENTION

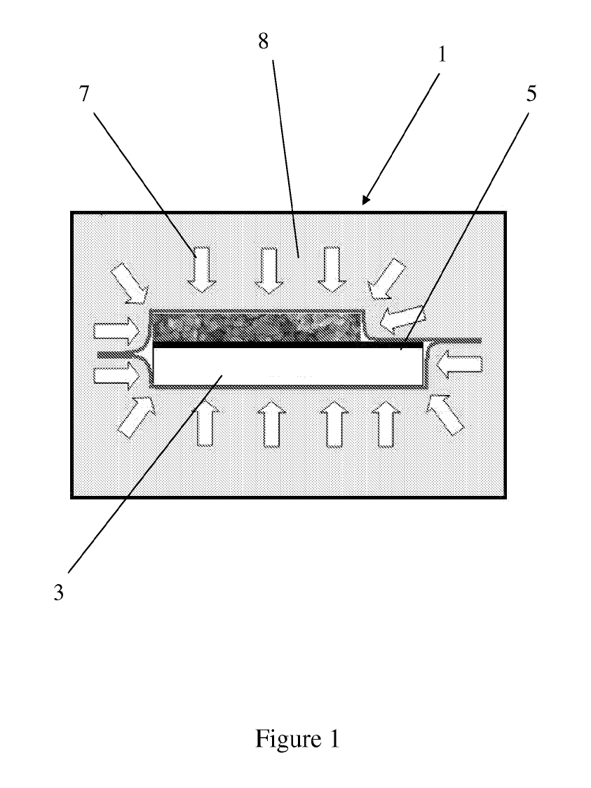

Referring initially to FIG. 1, there is shown a pressure chamber 1 within which is supported a substrate 3 sealed within a flexible bag 5. In the case of the manufacture of a flexible DSSC, the substrate 3 is made from a polymer material (typically, an ITO-PEN film), and is coated with a TiO₂ film 7. The coated substrate 3 is vacuumed sealed within the flexible bag 5, and then subjected to cold isostatic pressing (CIP) 8 within the pressure chamber 1. This is achieved by using a liquid media 9, typically water or oil, as a pressure medium within the pressure chamber 1. High pressure, in the order of tens to several hundred MPa, is applied through the liquid media 9 in all directions around the bag 5 containing the coated substrate 3 resulting in the compaction of the TiO₂ film 7 on the substrate 3. The use of CIP results in electrode films with high strength and uniformity being readily achieved. It also allows solar panels with curved or intricate shapes to be manufactured.

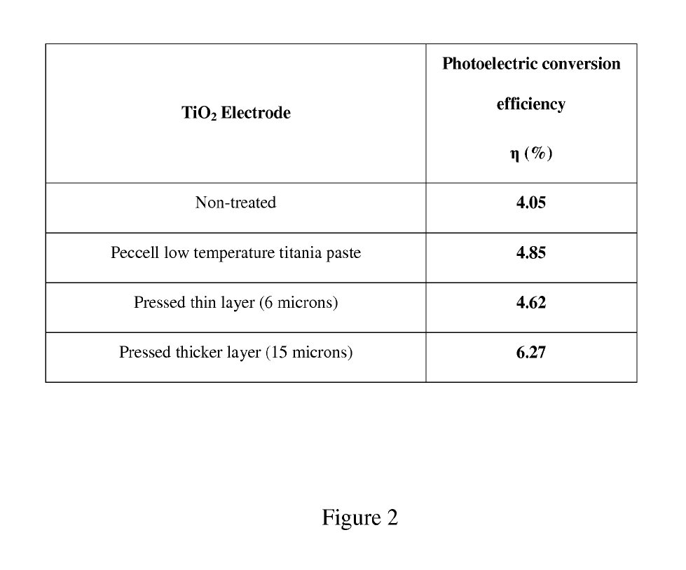

FIG. 2 is a Table showing experimental results comparing the photoelectric conversion efficiency of different TiO₂ electrodes. Degussa P-25 TiO₂ powders were used in all the devices except for commercially available Peccell paste. The experimentation was conducted to ascertain the viability of the method according to the present invention.

In conducting the experiments, commercial product Degussa P-25 TiO₂ powder was milled for five hours in a planetary ball mill. The slurry was then spread on ITO-PEN plastic substrates by doctor blading, which were then subjected to cold isostatic pressing (CIP) within a pressure chamber. Both CIP processed and non-CIP processed TiO₂ electrodes were used to assemble solar cells. Another solar cell device was made on the same polymer substrate using the commercially available low temperature TiO₂ slurry from Peccell Technologies, Inc. Japan. Photovoltaic properties of all these flexible DSSCs were tested for comparison. A maximum power conversion of 6.27% was obtained for the device having a film thickness of around 15 microns prepared by doctor bladed P-25 slurry followed by the CIP treatment.

Once the electrode film is compacted on the supporting substrate, the electrode film needs to be dye sensitised. This currently involves a production step in which the electrode film is soaked in a solution of photosensitive dye so that the dye molecules can be adsorbed into and dispersed through the electrode film layer. It can typically take around 10 to 12 hours for the soaking process to achieve satisfactory adsorption of the dye into the electrode film layer.

This soaking process may be avoided if the material used to form the electrode film is premixed with a photosensitive dye. Therefore, the electrode film coating the substrate surface will already be dye sensitised, and will therefore not need to undergo a further soaking process as previously described.

The starting electrode material can be in the form of a dry powder, such as TiO₂, or may be in the form of a colloid in a solution. This starting material can then be mixed with a sensitiser to form a liquid or paste that can then be coated or printed onto the substrate surface. The sensitiser can be photosensitive dye molecules. Other sensitisers such as quantum dots could however be used to sensitise the electrode film.

The result is that the production period for manufacturing a DSSC or other mesoscopic solar cells could be significantly reduced. Furthermore, the production process could be more readily adapted to be a continuous process, particularly when printing methods are used to print the electrode film (or functional layer) onto the substrate surface.

In the manufacture of conventional DSSC devices, the material coating the substrate surface needs to be heated to about 500° C. to form the final electrode film. It is therefore not possible to pre-dye this coating material because the dye becomes unstable and therefore inactive if exposed to temperatures above 200° C. The electrode film would therefore lose its dye sensitivity after undergoing heating at this high temperature. In the CIP process, the electrode film and the photosensitive dye absorbed in the film do not get exposed to high temperatures, and the dye will therefore retain its photosensitivity.

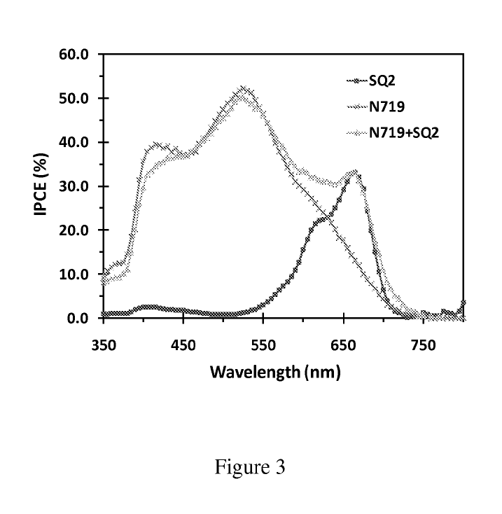

A number of different photosensitive dyes are available for use in the production of DSSCs to provide the required dye sensitization. Each of these dyes has a different light absorption range. Some dyes absorb more light within the visible range whereas others absorb more light in the infrared range. The light absorption range of any one of these dyes is however relatively limited which has the practical effect of limiting the photoelectric conversion efficiency of conventional DSSC devices. FIG. 3 is a graph showing the IPCE Spectra of two different photosensitive dyes (SQ2 and N719 respectively).

Attempts have been made to widen the light absorption range by using a mixture of different photosensitive dyes within the electrode film of the DSSC, with each dye having a different light absorption range. It has however been found that there is an interaction between the different dye molecules where the electrons emitted from the dye molecules of one type tend to migrate towards the dye molecules of the other type. This “quenching effect” between the two dye molecule types acts to restrict electron transportation to the conducting electrode. Therefore, only small benefits have been achieved by having a mixture of different dyes in the electrode film.

Further experimentation has found that this quenching effect may be avoided or minimised by having two or more electrode film layers supported on the substrate, with each electrode film layer supporting a different photosensitive dye. FIG. 3 also shows the combined IPCE Spectra (N719+SQ2) that can be achieved by a DSSC having a first electrode film supporting one dye, and a second electrode film supporting another dye overlying the first electrode film. The combined range extends from the visible (from N719) to near IR (from SQ2).

Because the different dyes are located in separate electrode films, this minimises or prevents any quenching effect between the different dye types. Therefore, the light absorption range of this DSSC can be extended to cover a broader range preferably extending from the near infrared, to the infrared range, and through into the visible range.

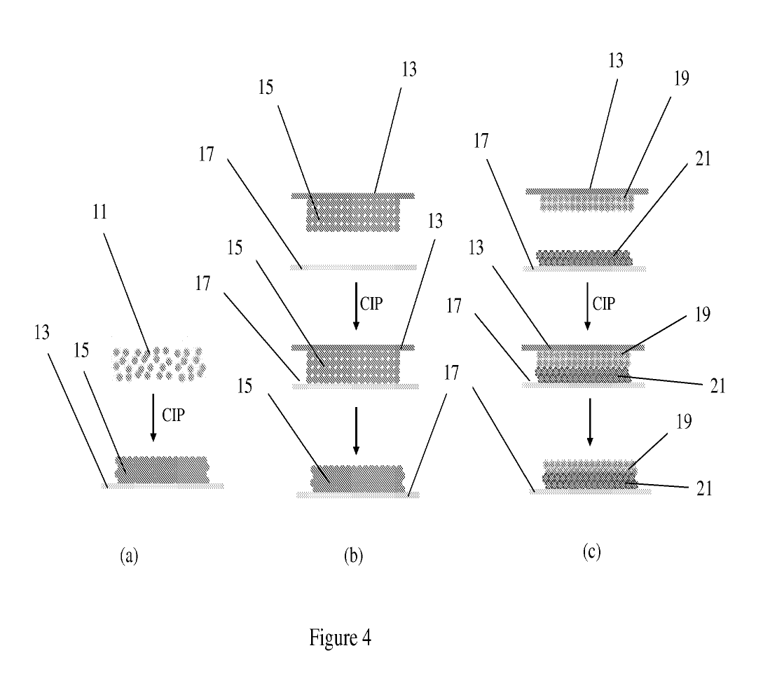

The CIP method facilitates the manufacture of a DSSC having a plurality of overlying electrode film layers, each supporting a different dye. FIG. 4 (a) to (c) shows how this can be achieved.

FIG. 4 (a) shows schematically how loosely packed particles or sensitised particles 11 of electrode material can be compacted onto a first substrate 13 to form an electrode film 15 using CIP. This method has been previously described in relation to FIG. 1. FIG. 4 (b) shows that it is possible to transfer the electrode film 15 to a second substrate 17. The electrode film 15 is laid over the second substrate 17, and CIP applied to both the first and second substrates 13, 17 and the electrode film 15. This results in the transfer of the electrode film 15 onto the second substrate 17, the electrode film 15 separating from the first substrate 13.

FIG. 4 (c) shows a first electrode film 19 sensitised with a first sensitiser and supported on a first substrate 13. A second electrode film 21 sensitised with a second sensitiser is shown supported on a second substrate 17. The first and second electrode films may be sensitised after being coated on their respective substrates or may be formed from sensitised particles as previously discussed.

The first and second substrates 13, 17 are then placed side to side with their electrode films 19, 21 in face to face direct contact. Finally, the assembled first and second substrates are together subjected to CIP. This results in the first electrode film 19 being compacted onto the second electrode film 21. The second substrate 13 can then be separated from the first electrode film 13. This step may be repeated where further electrode film or other functional layers are required to be added.

Alternatively, a first electrode film layer sensitised with a first sensitiser may initially be formed on a first substrate surface as previously described. Loosely packed sensitised particles of electrode material sensitised with a second sensitiser may then be spread over the first electrode. Isostatic pressure may then be applied to compact the loosely packed material onto the first electrode film to thereby form a second electrode film. This process can be repeated if further electrode film or other functional layers are required.

The resultant DSSC manufactured according to the present invention has an extended light absorption range which can potentially lead to DSSCs with higher photoelectric conversion efficiencies than currently available DSSCs.

Modifications and variations as would be deemed obvious to the person skilled in the art are included within the ambit of the present invention as claimed in the appended claims.

1. A method of manufacturing a dye sensitised solar cell or other mesoscopic solar cell, including the steps of:
a) coating at least a portion of a surface of a substrate with an electrode film or other functional layer, and
b) applying an isostatic pressure over the coated substrate to thereby compact the electrode film or functional layer on the substrate.

2. A manufacturing method according to claim 1, wherein the material forming the electrode film includes TiO2.

3. A manufacturing method according to claim 1, wherein the material forming the electrode film includes carbon.

4. A manufacturing method according to claim 1, wherein the functional layer includes a counter electrode or a conducting layer.

5. A manufacturing method according to claim 1, wherein the electrode film material is premixed with a sensitizer.

6. A manufacturing method according to claim 1, wherein the electrode film material is premixed with a photosensitive dye.

7. A manufacturing method according to claim 1, including forming a first said electrode film on a first said substrate, forming a second said electrode film on a second said substrate, bringing the first and second electrode films in face to face contact, subjecting the first and second electrode films to isostatic pressure to thereby compact the second electrode film to the first electrode film, and separating the second substrate from the second electrode film.

8. A manufacturing method according to claim 1, including forming a first said electrode film on a said substrate, applying a second said electrode film in the form of a powder over the first electrode film, and applying isostatic pressure on the first and second electrode films to compact said second electrode film on the first electrode film.

9. A manufacturing method according to claim 7, wherein the first electrode film is sensitised with a first sensitiser, whereas the second electrode film is sensitised with a second sensitiser.

10. A manufacturing method according to claim 1, wherein the substrate is flexible, and is formed from a polymer material.

11. A manufacturing method according to claim 1, wherein the substrate is rigid, and is formed from a metal, ceramic or glass material.

12. A manufacturing method according to claim 1, wherein the isostatic pressure is applied to the coated substrate by sealing the coated substrate within a flexible mold or bag, and applying the isostatic pressure to the coated substrate within a pressure chamber.

13. A manufacturing method according to claim 10, wherein liquid or gas is used as a pressure medium within the pressure chamber.

14. A manufacturing method according to claim 1, wherein the isostatic pressure is applied in either a free mold, coarse mold or fixed mold process.

15. A manufacturing method according to claim 11, wherein the pressure medium is heated.

16. A manufacturing method according to claim 1, wherein the electrode film or other functional layer is applied using a printing process.

17. A mesoscopic solar cell manufactured according to the method of claim 1.

18. A manufacturing method according to claim 8, wherein the first electrode film is sensitised with a first sensitiser, whereas the second electrode film is sensitised with a second sensitiser.
